(19) United States
(12) Patent Application Publication
(10) Pub. No.: US 2008/0105455 A1
(43) Pub. Date: May 8, 2008

(54) CIRCUIT BOARD WITH REGIONAL FLEXIBILITY

(75) Inventors: Paul Palfreyman, Port Moody (CA); Lawrence Schmeikal, Coquitlam (CA)

Correspondence Address: MORRISON & FOERSTER LLP, 12531 HIGH BLUFF DRIVE, SUITE 100, SAN DIEGO, CA, 92130-2040, US

(73) Assignee: TIR Systems Ltd., Burnaby (CA)

(21) Appl. No.: 11/870,363

(22) Filed: Oct. 10, 2007

Related U.S. Application Data
(60) Provisional application No. 60/850,920, filed on Oct. 10, 2006.

(51) Int. Cl. H05K 1/00; H05K 3/00

(52) U.S. Cl. 174/254; 29/829

(57) ABSTRACT

The present invention provides a printed circuit board (PCB) adapted to reduce stress due to coupling of a structure to two different areas of the PCB. The invention involves mechanically isolating an area of the PCB intended for coupling with the structure by forming a stress-relief region around the area in order to create a localised movable area. By introducing such localised flexibility into the PCB in at least the area of one coupling, any build-up of stress due to the coupling of the structure can be mitigated.

### CROSS-REFERENCE TO RELATED APPLICATIONS

This application is a Non-Prov of Prov (35 USC 119(e)) application 60/850,920 filed on Oct. 10, 2006.

### FIELD OF THE INVENTION

The present invention pertains to the field of circuit board design and, in particular, to a circuit board with regional flexibility.

### BACKGROUND

In the electronics industry, it is customary to employ printed circuit boards (PCBs) wherein much of the circuit wiring and electronic components are mounted on a common base. In general, a printed circuit board usually comprises a relatively rigid base on which a pattern of printed wires is formed in some predetermined configuration. The printed wiring can be etched from a previously deposited layer of copper cladding. The printed wiring generally includes narrow conductive strips called “circuit traces” and broad conductive surfaces called “pads”. The traces and pads provide a connecting electrical map for the separately manufactured electronic components, such as resistors, transistors, capacitors, light-emitting diodes (LEDS), etc. An electronic component is typically mounted on a printed circuit board by soldering onto the pads or by other processes well known in the art to produce a conductive contact between the electronic component's terminals and the printed wiring.

A number of techniques are well known and may be used for mounting electronic components on printed circuit boards. One technique involves the use of surface-mounted components. As is known, the conductive surfaces of such surface-mounted components are usually soldered directly to the conductive pads described above. Although serving the purpose, this mounting technique, by itself, has not proved entirely satisfactory under all conditions of service.

A problem occurs when a structure, such as a heat pipe, is to be coupled to an electronic component which is mounted on an industry standard printed circuit board. In many cases the positions of the structure (e.g. heat pipe) and PCB will be in fixed relation to each other, for example due to necessary alignment with a housing. Often, due to the normal manufacturing tolerances of a heat pipe, housing and PCB, as well as tolerances in the size and alignment of the electronic component, the surface of the heat pipe does not align precisely with the surface of the electronic component to which it is to be coupled. If the contact is forced, stresses are introduced into the coupling or connection which can lead to a resulting short lifetime of the coupling and, subsequently, electronic component. Specifically, the coupling will become more likely to fail due to thermo-mechanical stresses induced as the PCB and electronic component are thermally cycled.

Therefore, a problem confronting designers is achieving sufficient physical stability for an electronic component mounted on a PCB that is to be coupled to a structure which in turn is coupled to another area of the PCB, while limiting stresses induced by this coupling.

This background information is provided to reveal information believed by the applicant to be of possible relevance to the present invention. No admission is necessarily intended, nor should be construed, that any of the preceding information constitutes prior art against the present invention.

### SUMMARY OF THE INVENTION

An object of the present invention is to provide a circuit board with regional flexibility. In accordance with an aspect of the present invention, there is provided a printed circuit board comprising: a top surface; a bottom surface; one or more stress relief regions extending at least partially between said top surface to said bottom surface, said one or more stress relief regions identifying a localised movable area of the printed circuit board; said localised movable area adapted for receiving a structure coupling said localised movable area and another area of the printed circuit board; wherein said one or more stress relief regions are configured to reduce stress induced by coupling of the structure.

In accordance with another aspect of the present invention, there is provided a printed circuit board comprising: two or more regions, at least a first of said regions being flexible relative to at least a second of said regions; one or more stress relief regions defined within the printed circuit board, said one or more stress relief regions configured to provide flexibility between said first region and said second region; said first region adapted for coupling to a first component, said second region adapted for coupling to a second component, said first component mechanically coupled to said second component, wherein flexibility between said first and said second regions allows for a decrease in stress induced by the coupling of the printed circuit board to said first and said second components.

In accordance with another aspect of the present invention, there is provided a method of preparing a printed circuit board, the method comprising forming one or more stress relief regions at least partially through the printed circuit board, said one or more stress relief regions identifying a localised movable area of the printed circuit board, said localised movable area adapted for receiving a structure coupling said localised movable area and another area of the printed circuit board, wherein said one or more stress relief regions are configured to reduce stress induced by coupling of the structure.

In accordance with another aspect of the present invention, there is provided a method of assembling a printed circuit board comprising the steps of: forming one or more stress relief regions at least partially through the printed circuit board, said one or more stress relief regions defining a localised movable area of the printed circuit board; and coupling a structure to said localised movable area and another area of the printed circuit board; wherein said one or more stress relief regions are configured to reduce stress induced by coupling of the structure.

### BRIEF DESCRIPTION OF THE FIGURES

FIG. 1 is a top view of a printed circuit board incorporating a single localised movable area according to one embodiment of the present invention.

FIG. 2 is a top view of a printed circuit board incorporating a single localised movable area according to another embodiment of the present invention.

FIG. 3 is a top view of a printed circuit board incorporating a single localised movable area according to another embodiment of the present invention.

FIG. 4 is a sectional view taken along line 2-2 of FIG. 3.

FIG. 5 is a sectional view taken along line 3-3 of FIG. 3.

FIG. 6 is a top view of a printed circuit board incorporating a single localised movable area according to a further embodiment of the present invention.

FIG. 7 is a top view of a printed circuit board incorporating a single localised movable area according to another embodiment of the present invention.

FIG. 8 is a sectional view of another embodiment of the present invention that incorporates partial routing through the underside of the printed circuit board proximate to the localised movable area.

FIG. 9 is a top view of a printed circuit board incorporating multiple localised movable areas according to another embodiment of the present invention.

FIG. 10 is a bottom view of the printed circuit board in FIG. 9.

FIG. 11 is a top view of a printed circuit board incorporating a single localised movable area according to another embodiment of the present invention.

### DETAILED DESCRIPTION OF THE INVENTION

### Definitions

The term “printed circuit board” (PCB) is used to define a circuit board which is selected from a variety of configurations, for example a FR4 board, a metal core printed circuit board (MCPCB), a board formed from a cast polymer resin that is cross linked using ultraviolet radiation, or other circuit board configuration as would be readily understood by a worker skilled in the art.

The term “light-emitting element” is used to define a device that emits radiation in a region or combination of regions of the electromagnetic spectrum for example, the visible region, infrared and/or ultraviolet region, when activated by applying a potential difference across it or passing a current through it, for example. Therefore a light-emitting element can have monochromatic, quasi-monochromatic, polychromatic or broadband spectral emission characteristics. Examples of light-emitting elements include semiconductor, organic, or polymer/polymeric light-emitting diodes, optically pumped phosphor coated light-emitting diodes, optically pumped nano-crystal light-emitting diodes or other similar devices as would be readily understood by a worker skilled in the art. Furthermore, the term light-emitting element is used to define the specific device that emits the radiation, for example a LED die, and can equally be used to define a combination of the specific device that emits the radiation together with a light-emitting element housing or package within which the specific device or devices are placed.

As used herein, the term “about” refers to a +/−10% variation from the nominal value. It is to be understood that such a variation is always included in any given value provided herein, whether or not it is specifically referred to.

Unless defined otherwise, all technical and scientific terms used herein have the same meaning as commonly understood by one of ordinary skill in the art to which this invention belongs.

The present invention provides an apparatus and method configured to relieve stress induced due to the coupling of a structure to two different areas of a printed circuit board (PCB). The present invention pertains to the provision of a localised movable area within a PCB. The localised movable area allows for relative flexibility between the two different coupling areas of the PCB. The present invention can be used for relieving the stress induced due to a coupling between an electronic component (e.g. light-emitting element) mounted on a printed circuit board (PCB) and other structure or component on the PCB or external to it. In this case the localised movable area permits the mounting of an electronic component which may undergo movement or that may need to be connected to a structure (e.g. heat pipe) which may not be precisely aligned with the electronic component.

By introducing localised flexibility into the PCB in the area (or region) of at least one of the structure couplings, stresses induced by the coupling of the structure can be mitigated. In one embodiment, the localised movable area is able to move in a direction perpendicular to the PCB in order to provide appropriate displacement of the electronic component in three orthogonal directions, if required.

The present invention involves partially mechanically isolating the intended area for receiving a structure on the PCB from another area of the PCB by the formation of a stress-relief region around the intended area thereby forming a localised movable area. It will be appreciated that the present invention also includes the formation of a stress-relief region after coupling to the structure. The stress-relief region is configured such that the resulting localised movable area remains connected to the main portion of the PCB by reduced portions of PCB material, for example strips or connecting regions of PCB material, wherein the connecting regions are sufficiently long to provide a desired relative flexibility between the localised movable area and the PCB.

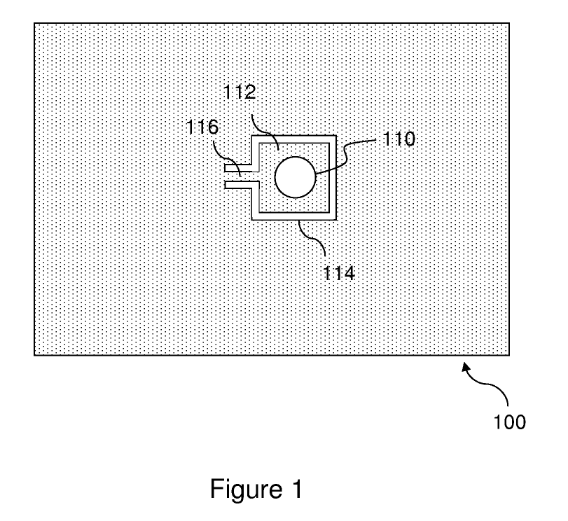

For example, FIG. 1 is a top view of a printed circuit board (PCB) 100 according to one embodiment of the present invention. In FIG. 1, a localised movable area 112 of the PCB 100 is adapted for receiving a structure 110 coupled with another area of the PCB 100. The localised movable area 112 is identified by a slot 114 and is connected to the rest of the PCB 100 via a single connecting region 116. The connecting region 116 also maintains electrical connection of the localised movable area 112 to the rest of the PCB 100. This formation of a localised movable area 112 connected via a single connecting region 116 can be defined as a single connection formation. The single connecting region 116 is configured to deform through flexure, torsion, or a combination thereof, thereby allowing for movement of the localised movable area 112 relative to the remainder of the PCB. It will be understood that the slot 114 may have other shapes such as semicircular or semi-oval or other shape as would be readily understood by a worker skilled in the art. It will also be understood that the connecting region 116 can have different sizes and shapes, wherein modification of these aspects of a connecting region can allow for more or less flexure and/or more or less torsion.

Stress Relief Region

The stress relief region enables relative movement between the localised movable area and another area of the PCB to which it is connected. It will be appreciated that the size and shape of the stress-relief region introduced into the PCB may be chosen in a manner that enables the provision of a desired amount of relative flexibility between the localised movable area and another portion of the PCB. Furthermore, a suitable shape and configuration of a stress-relief region may be fabricated into a PCB in order to identify a localised movable area adapted for receiving a structure coupled with another area of the PCB.

In one embodiment, an electronic component is mounted on the localised movable area which is coupled to a heat management system structure. This heat management system structure in turn is coupled to another area of the PCB such as another localised movable area of the PCB, or the periphery of the PCB via, for example, an exterior panel or housing. The structure could also be a thermosyphon, a heat sink, a heat exchanger, a heat pipe, a housing, an exterior panel, or a suitable combination thereof. In general, the stress-relief region provides sufficient flexibility in order that the localised movable area is able to move in at least one direction. In one embodiment, the localised movable area will also be movable in at least two dimensions. In another embodiment, the localised movable area will also be movable in a direction perpendicular to the PCB.

In one embodiment, the stress relief region is formed by one or more slots which are introduced into the PCB and may be configured in a desired manner to provide the required amount of flexibility. In one embodiment, a suitable shape and configuration of slots are fabricated into a PCB in order to identify a localised movable area on which an electronic component, susceptible to alignment mismatches, may be mounted. In some embodiments the slots fabricated in the PCB can be configured such that the localised movable area formed remains connected to the main stiffer area of the PCB by relatively long narrow connecting regions or strips of PCB material.

In one embodiment of the present invention, the range of movement for a localised movable area within a PCB may be increased by removing a portion of the material of the PCB proximate to one or more slots. For example, the area of the PCB proximate to the slots may be thinned by routing, for example, in order to reduce the thickness of the PCB in the desired area.

In another embodiment of the present invention, the stress relief region is formed solely by a reduction of the thickness of the PCB material at desired locations, for example by forming channels within the PCB which define the localised movable area. These channels can provide regions of reduced thickness and thus relative flexibility with respect to a remainder of the PCB. This configuration of the stress relief region can provide a limited degree of flexibility to the localised movable area and may be suitable if a lower degree of flexibility is required to reduce stress induced by the coupling of a structure to the localised movable area and another area of the PCB.

Those skilled in the art will also appreciate that it is possible to include more than one localised movable area within a single PCB in order to allow flexibility of movement and correspondingly, stress relief, in relation to several structures mounted on the PCB. If there is more than one localised movable area within a single PCB, these localised moveable areas can all be configured as the same type, or they can be configured as a variety of different types. Furthermore, the technique of forming localised movable areas within a PCB may become more important when several components mounted on a single PCB need to be coupled to structures which are also coupled to another area of the PCB such as other localised movable areas, or the perimeter of the PCB via a housing or exterior panel.

It will also be appreciated that the slots need not be linear in nature, but may be curved or bent into a desirable and suitable configuration including configurations made up of a combination of linear, curvilinear, semi-triangular, semicircular, semi-oval, semi-elliptical, semi-rectangular and L-shaped portions or other shapes as would be readily understood by a worker skilled in the art.

In one embodiment of the present invention, where the PCB has been routed or grooved, the depth of routing or grooving can be varied along the groove or channel.

In one embodiment of the present invention, subsequent to interconnection between a PCB and a structure, the one or more stress relief regions can be reinforced, for example by infilling or other process or manner, in order to provide additional mechanical integrity between a localized movable area and the remainder of the PCB. For example, this additional mechanical integrity may be required for applications where vibrations may be anticipated, or other applications as would be readily understood.

Formation of Stress Relief Region

Those skilled in the art will appreciate that numerous methods exist of introducing a stress-relief region into a PCB such that a resulting localised movable area remains connected to the main stiffer area of the PCB. For example, a stress-relief region may be formed by punching through the PCB substrate with an appropriate punching apparatus although other methods, such as routing, cutting or sawing may be used. In one embodiment, a stress-relief region may be formed at the same time that guide or alignment holes are formed, wherein these guide or alignment holes may be used by processing equipment for alignment purposes during manufacturing of the PCB.

Those skilled in the art will appreciate that a stress-relief region may be readily formed during the moulding process or may be cut at a later time before or after a required etching process.

Those skilled in the art will appreciate that the stress induced by the coupling of a structure, directly or indirectly to two different areas of a PCB, may be mitigated by slots identifying a localised movable area for at least one of the two different coupling areas. Examples of such a structure are a potentiometer or switch mounted on a PCB that may need to be coupled directly or indirectly to another area of the PCB, such as a housing or an exterior panel. In this case, localised flexibility in the region of the potentiometer or switch will, advantageously, accommodate a mismatch in alignment thereby reducing stress at the coupling. Those skilled in the art will also appreciate that an electronic component resident on a PCB that needs to be coupled to a structure which is also coupled directly or indirectly to another area of the PCB may be mounted on a localised movable area of the PCB can decrease stress induced due to the coupling. Common examples of such electronic components include light-emitting elements, potentiometers, diodes or other electronic components which generate heat and may need to be connected to some kind of thermal management system.

In one embodiment of the present invention, a PCB can be manufactured from a cast polymer resin that is cross-linked using ultraviolet radiation to produce a stiff board, which may be suitable for electroplating for example. In this embodiment, by selectively masking the UV irradiation, selected regions of the board could have reduced rigidity that may allow the thereby defined localized movable area to flex relative to the remainder of the board. In one embodiment, upon mating of the PCB with the structure, additional UV radiation could subsequently applied to complete the polymerization of the cast polymer resin, thereby resulting in a substantially rigid board.

### EXAMPLES

### Example 1

FIG. 1 is a top view of a printed circuit board (PCB) 100 configured according to one embodiment of the present invention. In FIG. 1, a localised movable area 112 of the PCB 100 is adapted for receiving a structure 110 coupled with another area of the PCB 100. The localised movable area 112 is identified by a slot 114 and is connected to the rest of the PCB 100 via a single connecting region 116. The connecting region 116 can also maintain electrical connection of the localised movable area 112 to the rest of the PCB 100. This configuration of a localised movable area 112 connected via a single connecting region 116 can be defined as a single connection formation. The single connecting region 116 is configured to deform through flexure, torsion, or a combination thereof, thereby allowing for movement of the localised movable area 112 relative to other portions of the PCB. It will be understood that the slot 114 may be configured in other shapes such as semicircular or semi-oval or the like. It will also be understood that the connecting region 116 can have different sizes and shapes and allow for more or less flexure and/or more or less torsion.

### Example 2

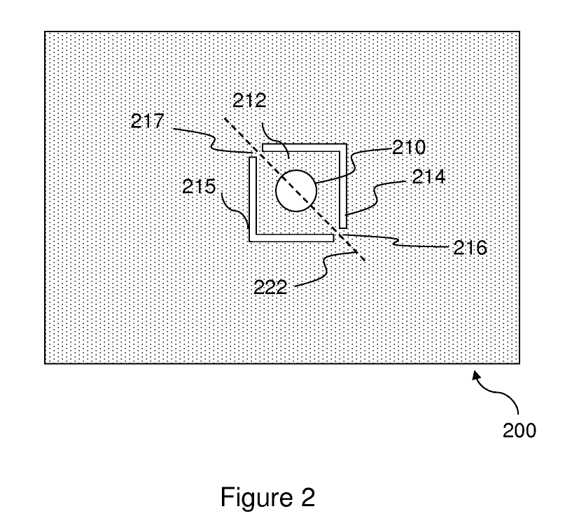

FIG. 2 is a top view of a PCB 200 according to another embodiment of the present invention. In FIG. 2, a localised movable area 212 of the PCB 200 is adapted for receiving a structure 210 coupled with another area of the PCB 200. The localised movable area 212 is identified by slots 214 and 215 and is connected to the remainder of the PCB 200 via two connecting regions 216 and 217 which are substantially opposite each other across the localised movable area 212. This configuration of a localised movable area 212 connected via two connecting regions 216 and 217 can be defined as a double connection formation. The double connection formation is configured to allow for rotation of the localised movable area 212 about an effective axis of rotation 222 identified by the two connecting regions 216 and 217.

It will be understood that the two substantially opposed connecting regions 216 and 217 may be located across a given region of the localised movable area 212 and not necessarily across the middle of the localised movable area 212. For example, in one embodiment of the present invention, the localised movable area can rotate about an effective axis of rotation that is close to one side of the localised movable area. The effective axis of rotation identified by the two connecting regions can be variable and can shift or rotate, to an extent determined by the sizes and shapes of the two connecting regions, thereby allowing for variability in the axis of rotation of the localised movable area relative to the remainder of the PCB. For example, larger connecting regions can allow for greater variability in the effective axis of rotation. In one embodiment the effective axis of rotation can rotate between 0° and about 45°. In another embodiment the effective axis of rotation can rotate between 0° and about 30°. In another embodiment the effective axis of rotation can rotate between 0° and about 10°.

### Example 3

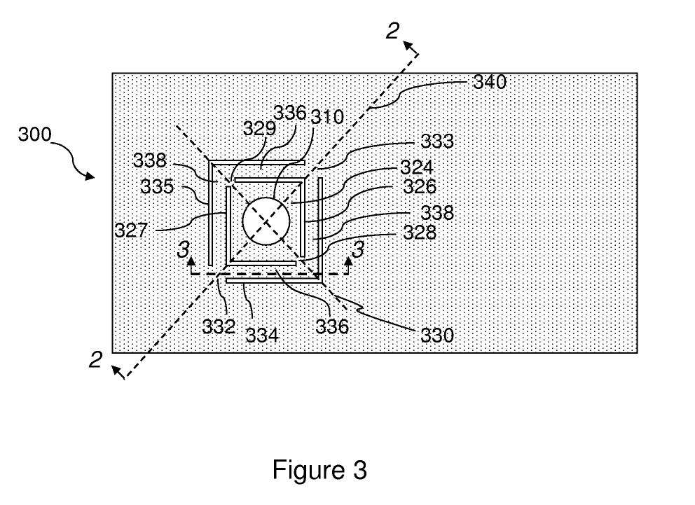

FIG. 3 is a top view of a PCB 300 according to another embodiment of the present invention. In FIG. 3, a localised movable area of the PCB 300 is adapted for receiving a structure 310 coupled with another area of the PCB 300. The localised movable area comprises two localised movable subareas which are nested wherein one localised movable subarea is located within the other. In this configuration, there are two double connection formations; the inner double connection formation comprises smaller localised movable subarea 324, identified by L-shaped slots 326 and 327, and two connecting regions 328 and 329 which are configured to allow for rotation of localised movable subarea 324 about an effective axis of rotation 330. The outer double connection formation comprises two connecting regions 332 and 333 and the larger localised movable subarea, identified by L-shaped slots 334 and 335, which includes both localised movable subarea 324 and the areas 336 and 338. These connecting regions 332 and 333 are configured to allow for rotation of the larger localised movable subarea about an effective axis of rotation 340. In this figure the respective axes of rotation 330 and 340 of the two double connection formations are substantially perpendicular, however these axes of rotation may intersect at an angle less than or greater than 90 degrees.

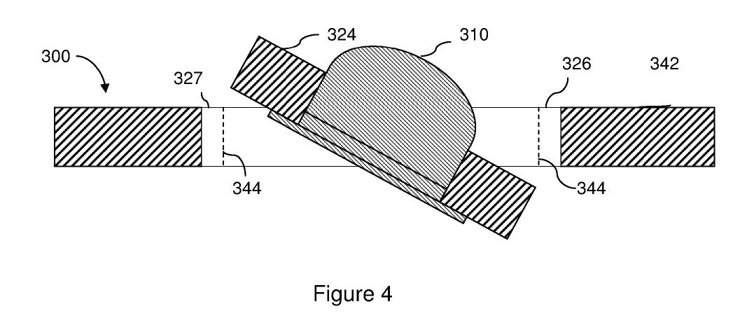

FIG. 4 is a cross-sectional view of the PCB 300 in FIG. 3 taken along dashed diagonal 2-2, wherein localised movable subarea 324 of the inner double connection formation has been rotated about effective axis of rotation 330. As illustrated in FIG. 4, the structure 310 remains attached to the localised movable subarea 324 as the localised movable subarea 324 is subjected to a displacing force and is rotated clockwise away from the plane of the PCB area 342 surrounding the localised movable area of the PCB 300. When no displacing force is present, the edges of the localised movable subarea 324 may revert to positions as indicated by dashed lines 344. Those skilled in the art will appreciate that the localised movable subarea 324 also can rotate in the opposite or counter clockwise direction (not shown).

In a similar fashion, the outer double connection formation permits the larger localised movable subarea, comprising localised movable subarea 324 and the areas identified by numbers 336 and 338, to rotate about an effective axis of rotation 340 substantially perpendicular to the effective axis of rotation 330 of the inner double connection formation.

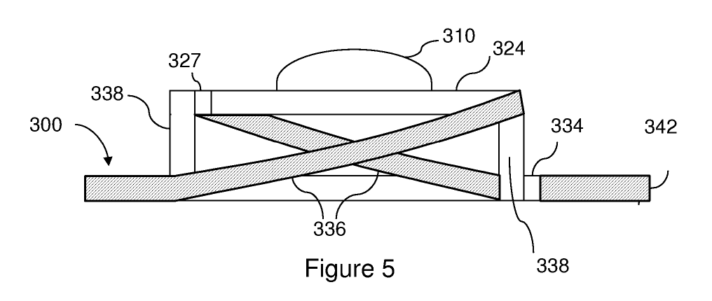

FIG. 5 is a cross-sectional view of the PCB 300 in FIG. 3 taken through dashed line 3-3, wherein localised movable subarea 324 is displaced perpendicular to the PCB area 342 surrounding the localised movable area. In this instance, the localised movable subarea 324 remains parallel to the PCB area 342 surrounding the localised movable area while areas 336 and 338 of the larger localised movable subarea slope upwards from the PCB area 342 surrounding the localised movable area of the PCB 300 to the localised movable subarea 324.

### Example 4

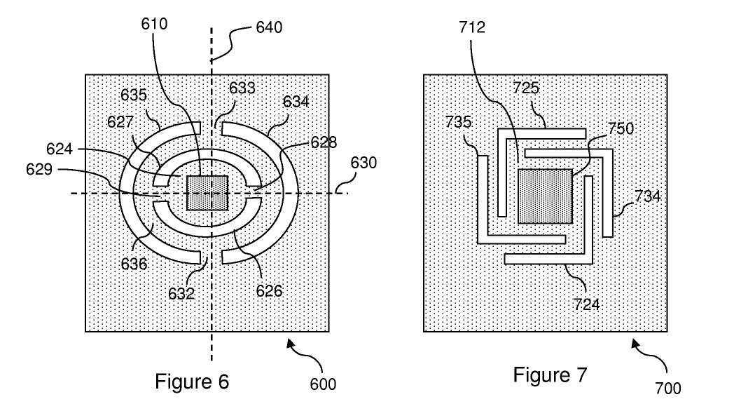

FIG. 6 is a top view of a PCB 600 according to another embodiment of the present invention. In FIG. 6, a localised movable area is identified by inner C-shaped slots 626 and 627 and outer C-shaped slots 634 and 635. As illustrated, the outer C-shaped slots 634 and 635 are substantially concentric with the inner C-shaped slots 626 and 627. The localised movable area comprises two localised movable subareas. The inner localised movable subarea 624 is identified by slots 626 and 627 and is part of a double connection formation which also comprises two connecting regions 628 and 629 which are located substantially opposite each other across the localised movable subarea 624 and are configured to allow for rotation of the localised movable subarea 624 about an effective axis of rotation 630. The larger localised movable subarea comprises localised movable subarea 624 and region 636. This larger localised movable subarea is also part of a double connection formation which comprises two connecting regions 632 and 633 which are configured to allow for rotation of the larger localised movable subarea about effective axis of rotation 640. This localised movable area is configured to reduce stress due to the coupling of a structure 610 coupled to localised movable subarea 624 and another area of the PCB by allowing for three-dimensional movement of the localised movable subarea 624. In one aspect of this embodiment, a component, such as a light-emitting element, which is to be coupled to a structure 610 which is also coupled to another area of the PCB 600, may then be mounted or coupled within the localised movable subarea 624.

It will be understood that in all embodiments comprising an effective axis of rotation, the effective axis of rotation can shift or rotate to an extent determined or allowed by the relevant configuration of the associated connecting regions.

### Example 5

FIG. 7 is a top view of a PCB 700 according to another embodiment of the present invention. In FIG. 7, there are two partially nested, for example positioned so that they are partially inside one other, double connection formations, one with a localised movable subarea identified by slots 724 and 725 and the other with a localised movable subarea identified by slots 734 and 735. A component 750, such as a light-emitting element, which is to be coupled to a structure which is also coupled to another area of the PCB 700, may then secured or mounted within the localised moveable area 712. In this manner, relative movement between the localised movable area and the remainder of the PCB is enabled.

### Example 6

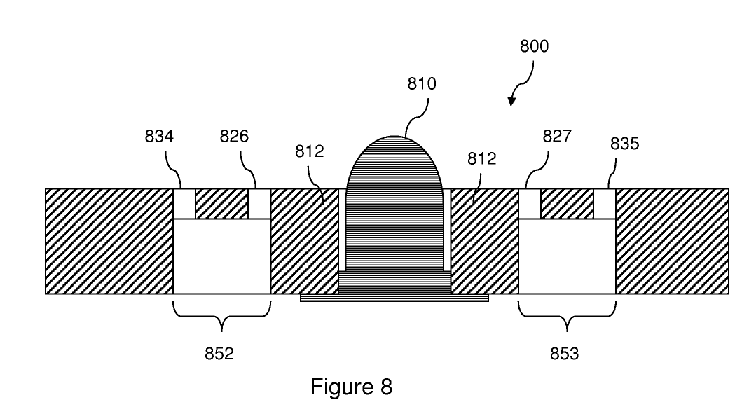

FIG. 8 is a cross-sectional view of a portion of a PCB 800. As discussed above, the range of movement for a localised movable area within a PCB may be increased by removing a partial thickness of the PCB proximate to one or more slots. For example, the area of the PCB proximate to the slots may be thinned by removing a portion of the PCB in this region, by routing for example. As illustrated in FIG. 8, PCB 800 includes partial routing of the PCB in order to improve flexibility. In this example, inner slots 826 and 827 outer slots 834 and 835 identify a localised movable area 812 adapted for receiving a structure 810 coupled to another area of the PCB 800. As can be seen, partially thinned areas 852 and 853 of the PCB 800 are created by routing, from the underside, through a portion of the thickness of the PCB proximate to slots 826 and 827, and 834 and 835. The partial routing of the PCB can extend through a predetermined portion of the thickness of the PCB, wherein this predetermined portion can be determined based on required flexibility provided to the localised movable area 812. For example, the partial routing may extend to a depth of about ¼ ½, ¾ or other portion of the thickness of the PCB 800. Similarly, the thickness of the PCB 800 can be a standard board thickness of about 0.06 inches, or other thickness, which can depend on the selection of the type and configuration of the PCB, as would be readily understood. In some embodiments of the present invention, reduction of the thickness of a PCB can be enabled by removal of material from the top or bottom of the PCB, or both.

### Example 7

Those skilled in the art will appreciate that it is possible to include more than one localised movable area within a single PCB in order to allow flexibility of movement and correspondingly, stress relief, in relation to several structures mounted on the PCB. Furthermore, the technique of forming localised movable areas within a PCB substrate may become more important when several components mounted on a single PCB need to be coupled to structures which are also coupled to another area of the PCB such as other localised movable areas, or the perimeter via a housing or exterior panel.

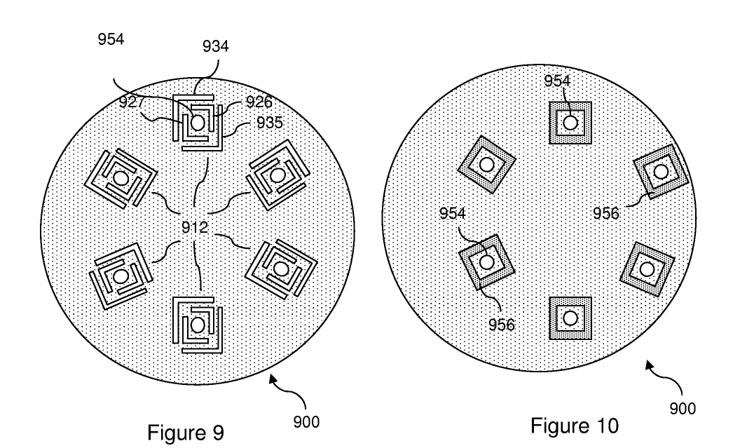

FIG. 9 illustrates another embodiment of the present invention, and illustrates a top view of a PCB 900 that includes a plurality of localised movable areas 912 for reducing stress build-up associated with the mounting of several structures as described above. In this particular example, PCB 900 comprises six localised movable areas 912. Each localised movable area 912 is comprised of two localised movable subareas each part of a double connection formation. The smaller localised movable subarea is identified by inner L-shaped slots 926 and 927 and the larger localised movable subarea is identified by outer L-shaped slots 934 and 935. The inner and outer L-shaped slots 926 and 927, 934 and 935 are similar in configuration to the example depicted in FIG. 3. In this example, the localised movable areas comprise structure connection points 954. For ease of illustration, only structure connection points 954 adapted for receiving electronic components to be mounted on PCB 900 are shown. It will be appreciated, however, that a different number of structure connection points and, correspondingly, localised movable areas may be introduced into a PCB substrate for the mounting of electronic components susceptible to any induced stress due to their couplings. Furthermore, multiple localised movable areas within one PCB can all be of the same configuration, or they can be a combination of two or more different configurations.

FIG. 10 is a bottom view of the PCB 900 depicted in FIG. 9. As indicated, the range of movement for each of the six localised movable areas 912 in FIG. 9 is increased by routing through a partial thickness of the PCB 900 proximate to slots 926 and 927 and slots 934 and 935 of each localised movable area 912. Specifically, for each localised movable area 912, a partially routed PCB region 956 corresponds to the area between the inner L-shaped slots 926 and 927 and the outer L-shaped slots 934 and 935. Routing through a partial thickness of the PCB 900 in this manner for each localised movable area 912 can increase the range of movement (i.e. flexibility) of the particular localised movable area 912.

### Example 8

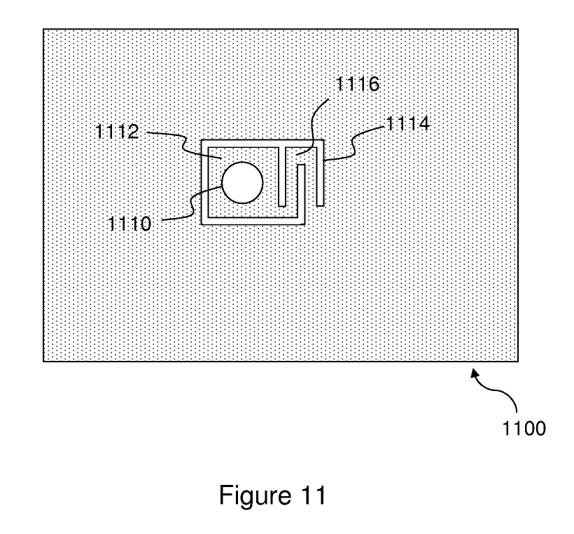

FIG. 11 is a top view of a PCB 1100 according to another embodiment of the present invention. In this embodiment the localised movable area 1112 adapted for coupling with a structure 1110 is identified by a single slot 1114. The slot 1114 is configured to leave an extended connecting region 1160 which doubles back beside itself around a portion of the slot to allow for moveability of the localised movable area 1112 in three dimensions. In a similar embodiment a single slot can be configured in the shape of a spiral leaving a long spiraling connecting region.

It is obvious that the foregoing embodiments of the invention are exemplary and can be varied in many ways. Such present or future variations are not to be regarded as a departure from the spirit and scope of the invention, and all such modifications as would be obvious to one skilled in the art are intended to be included within the scope of the following claims.

We claim:

1. A printed circuit board comprising:
a top surface;
a bottom surface;
one or more stress relief regions extending at least partially between said top surface to said bottom surface, said one or more stress relief regions identifying a localised movable area of the printed circuit board; said localised movable area adapted for receiving a structure coupling said localised movable area and another area of the printed circuit board,
wherein said one or more stress relief regions are configured to reduce stress induced by coupling of the structure.

2. The printed circuit board as claimed in claim 1 comprising two or more localised movable areas.

3. The printed circuit board as claimed in claim 1 wherein said localised movable area comprises two or more degrees of freedom.

4. The printed circuit board as claimed in claim 1 wherein one or more of said one or more stress relief regions form a slot configuration which identifies an effective axis of rotation.

5. The printed circuit board as claimed in claim 4 comprising two or more slot configurations each identifying a respective effective axis of rotation.

6. The printed circuit board as claimed in claim 5 wherein two of said respective effective axes of rotation are substantially perpendicular.

7. The printed circuit board as claimed in claim 5 wherein said two or more slot configurations are at least partially nested.

8. The printed circuit board as claimed in claim 1 wherein said localised movable area is connected to said another area via a single connecting region, said single connecting region configured to deform through flexure, torsion, or a combination thereof.

9. The printed circuit board as claimed in claim 1 wherein said localised movable area is connected to said another area via two connecting regions, said two connecting regions located substantially opposite each other across said localised movable area, said two connecting regions configured to allow for rotation of said localised movable area about an effective axis of rotation.

10. The printed circuit board as claimed in claim 1 wherein said localised movable area comprises one or more localised movable subareas, each of said localised movable subareas identified by one or more of said stress relief regions, wherein each of said localised movable subareas are configured for relative movement.

11. The printed circuit board as claimed in claim 10 comprising a single connection formation comprising one of said localised movable subareas and a single connecting region, said single connecting region configured to deform through flexure, torsion, or a combination thereof.

12. The printed circuit board as claimed in claim 11 comprising two single connection formations wherein one of said single connection formations is located within the other of said single connection formations.

13. The printed circuit board as claimed in claim 10 comprising a double connection formation comprising one of said localised movable subareas and two connecting regions which are located substantially opposite each other across said one of said localised movable subareas, said two connecting regions configured to allow for rotation of said one localised movable subarea about an effective axis of rotation.

14. The printed circuit board as claimed in claim 13 comprising two double connection formations which are at least partially nested.

15. The printed circuit board as claimed in claim 13 comprising two double connection formations having respective effective axes of rotation, wherein said respective effective axes of rotation are substantially perpendicular.

16. The printed circuit board as claimed in claim 15 wherein one of said double connection formations is located within the other.

17. The printed circuit board as claimed in claim 13 comprising one or more double connection formations, and one or more single connection formations comprising one of said localised movable subareas and a single connecting region, said single connecting region configured to deform through flexure, torsion, or a combination thereof, wherein said one or more double connection formations and said one or more single connection formations are at least partially nested.

18. The printed circuit board as claimed in claim 1 wherein the printed circuit board has a thickness, said thickness being reduced proximate to one or more of said one or more stress relief regions.

19. The printed circuit board of claim 1 wherein one or more of said stress relief regions is configured a slot having a shape selected from the group comprising: linear, curvilinear, semi-triangular, semicircular, semi-oval, semi-elliptical, semi-rectangular, and L-shaped.

20. A printed circuit board comprising:
two or more regions, at least a first of said regions being flexible relative to at least a second of said regions;
one or more stress relief regions defined within the printed circuit board, said one or more stress relief regions configured to provide flexibility between said first region and said second region; said first region adapted for coupling to a first component, said second region adapted for coupling to a second component, said first component mechanically coupled to said second component, wherein flexibility between said first and said second regions allows for a decrease in stress induced by the coupling of the printed circuit board to said first and said second components.

21. The printed circuit board as claimed in claim 20 wherein at least one of said regions comprises two or more degrees of freedom.

22. A method of preparing a printed circuit board, the method comprising forming one or more stress relief regions at least partially through the printed circuit board, said one or more stress relief regions identifying a localised movable area of the printed circuit board, said localised movable area adapted for receiving a structure coupling said localised movable area and another area of the printed circuit board, wherein said one or more stress relief regions are configured to reduce stress induced by coupling of the structure.

23. The method of claim 22, wherein one or more of said one or more stress relief regions is configured as a slot or a spiral extending from a top surface to a bottom surface of the printed circuit board.

24. The method of claim 22, wherein one or more of said one or more stress relief regions is configured as a channel formed within either a top surface or a bottom surface of the printed circuit board.

25. A method of assembling a printed circuit board comprising the steps of:
forming one or more stress relief regions at least partially through the printed circuit board, said one or more stress relief regions defining a localised movable area of the printed circuit board; and
coupling a structure to said localised movable area and another area of the printed circuit board;
wherein said one or more stress relief regions are configured to reduce stress induced by coupling of the structure.
